(19) United States
(12) Patent Application Publication
(10) Pub. No.: US 2008/0127484 A1
(43) Pub. Date: Jun. 5, 2008

(54) Selective filling of through holes

(75) Inventor: Joseph A.A.M. Tourne, Helmond (NL)

Correspondence Address: DUNLAP CODDING & ROGERS, P.C., PO BOX 16370, OKLAHOMA CITY, OK, 73113, US

(73) Assignee: Viasystems Group, Inc.

(21) Appl. No.: 11/633,904

(22) Filed: Dec. 5, 2006

(51) Int. Cl. H05K 3/42; H05K 7/08

(52) U.S. Cl. 29/830; 29/837; 361/679; 29/852

(57) ABSTRACT

A method for forming a mask for filling at least one target hole defined in a multilayer circuit board is described. In general, a removable layer is applied to an exterior surface of the multilayer circuit board. At least one access hole is then formed in the removable layer such that the at least one access hole in the removable layer overlaps with the at least one target hole to form the mask. Once the mask is formed, at least one target hole defined in the multilayer circuit board is filled with a fill material through the access hole formed in the removable layer. The fill material can be a conductive or nonconductive material. For example, the fill material can be conductive ink, or a conductive paste. In general, the fill material is a flowable material which can be positioned into the target hole through the access hole in its flowable state. Then, the fill material cures to form a hardened material within the target hole. The target hole can either be a through hole, or a blind hole. Once the fill material is positioned in the target hole, at least a portion of the removable layer is removed from the multilayer circuit board.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

The construction of multilayer circuit boards is well-known in the art. Prior art multilayer circuit boards are frequently provided with through holes which are subsequently plated, and filled with conductive or nonconductive material. A layer of a conductive material, such as copper, is then placed over the through hole to form a pad for connecting a surfacemount, or ball grid array component. For example, one exemplary prior art patent is U.S. Pat. No. 6,303,881, issued to Parker, Jr. et al. and entitled “Via Connector and Method of Making Same,” the entire content of which is hereby incorporated herein by reference. In the prior art patent, the plated via is filled with an electrically conductive filled composition. A conductive cap layer is formed on both ends of the conductive filled composition in the via and the major surfaces of the insulator substrate.

In the prior art, a stencil was commonly used for filling the through holes. In this process, a stencil having a preformed openings is aligned with the printed circuit board. Then, a squeegee or doctor blade is used to force the fill material into the through holes through the openings formed in the stencil.

Although the stencil and a squeegee or doctor blade adequately fills the through holes, there are some drawbacks to this process. For example, problems relating to flatness of the filling in the hole (i.e., dimpling at the surface), smearing ink under the stencil, cracking or air bubbling due to the quality of the filling, or problems relating to the adhesion of the plating with via fill resin.

### SUMMARY OF THE INVENTION

The present invention is related to a method for forming a mask for filling at least one target hole defined in a multilayer circuit board. In general, a removable layer is applied to an exterior surface of the multilayer circuit board. At least one access hole is then formed in the removable layer such that the at least one access hole in the removable layer overlaps with the at least one target hole to form the mask.

Once the mask is formed, at least one target hole defined in the multilayer circuit board is filled with a fill material through the access hole formed in the removable layer. The fill material can be a conductive or nonconductive material. For example, the fill material can be conductive ink, or a conductive paste. In general, the fill material is a flowable material which can be positioned into the target hole through the access hole in its flowable state. Then, the fill material cures to form a hardened material within the target hole. The target hole can be either a through hole, or a blind hole. Once the fill material is positioned in the target hole, at least a portion of the removable layer is removed from the multilayer circuit board.

In one preferred embodiment, the removable layer is constructed of a plastic film having an adhesive material thereon. The adhesive material is preferably constructed of an acrylic-based material, so as to leave only minimal or nonexistent residue on the multilayer circuit board after the removable layer has been removed.

In one embodiment, the present invention can also be characterized as a method for filling at least one target hole defined in the multilayer circuit board. In this method, the at least one target hole is plated with a conductive material, and then the removable layer is applied to the exterior surface of the multilayer circuit board. At least one access hole and preferably a plurality of access holes is then formed in the removable layer such that the at least one access hole in the removable layer overlaps with the at least one target hole in the multilayer circuit board to form a mask. The at least one target hole defined in the multilayer circuit board is then filled with the fill material through the access hole formed in the removable layer.

The exterior surface of the multilayer circuit board is preferably formed of a metallic material, such as copper plating. The step of forming the access hole in the removable layer is preferably formed with a laser configured to cut through the removable layer without cutting through the metallic material forming the exterior surface of the multilayer circuit board.

In yet another embodiment, the present invention can be characterized as a method for filling at least one target hole defined in multilayer circuit board. In this embodiment, the removable layer is applied to the exterior surface of the multilayer circuit board, and the at least one access hole is then formed in the removable layer such that the at least one access hole in the removable layer overlaps with the at least one target hole in the multilayer circuit board to form the mask. The target hole(s) defined in the multilayer circuit board is then filled with a conductive fill material, such as conductive ink or conductive paste, or a non-conductive material through the access hole. At least a portion of the removable layer is then removed from the multilayer circuit board, such as by peeling the removable layer from the multilayer circuit board. In this embodiment, the target hole can be either a plated or an unplated hole. The target hole can be a through hole or a blind hole.

Other embodiments, advantages and features of the present invention will be apparent to one skilled in the art when the following detailed description is read in view of the attached drawings and appended claims.

### BRIEF DESCRIPTION OF THE SEVERAL VIEWS THE DRAWING

FIG. 1 is a cross-sectional view of a multilayer circuit board constructed in accordance with the present invention.

FIGS. 2-9 cooperate to illustrate one preferred method for the selective filling of via holes constructed in accordance with the present invention.

More particularly, FIG. 2 illustrates a step of forming at least one target hole in a multilayer circuit board.

FIG. 3 illustrates a step of electrolessly plating the multilayer circuit board having the target hole formed therein.

FIG. 4 illustrates a step of applying a conductive coating to the multilayer printed circuit board.

FIG. 5 illustrates a step of applying a removable layer to each of the exterior surfaces of the multilayer circuit board.

FIG. 6 illustrates a step of forming access holes in the removable layers such that the access holes overlap with predetermined target holes formed in the multilayer circuit board.

FIG. 7 illustrates a step of filling the predetermined target holes through the access holes formed in the removable layer while the removable layer prevents access of the fill material to other predetermined holes formed in the multilayer circuit board.

FIG. 8 illustrates a step of removing the removable layer from each exterior surface of the multilayer circuit board.

FIG. 9 illustrates the step of planerizing the exterior surfaces of the multilayer circuit board such that any excess fill material is removed therefrom.

### DETAILED DESCRIPTION OF THE INVENTION

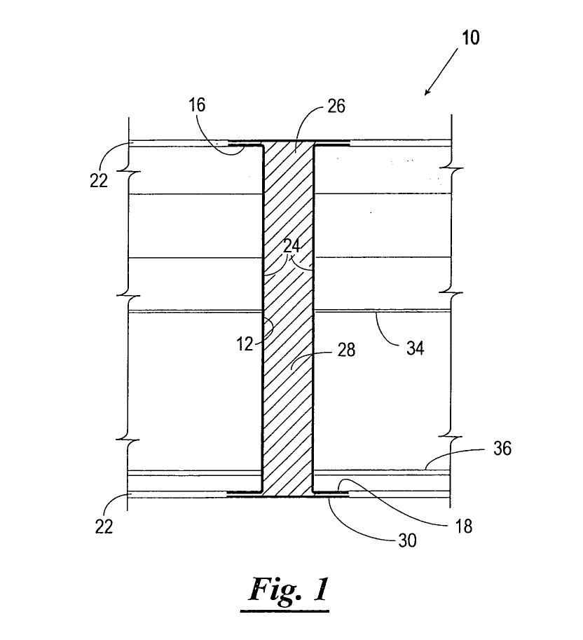

Referring now to the drawings, and in particular to FIG. 1, shown therein and designated by a reference 10 is an insulator substrate constructed in accordance with the present invention. The insulator substrate 10 can be a multilayer printed circuit board, or a flexible thin-film substrate. A through hole or via 12 is formed in the insulator substrate 10 at a desired position. Preferably, the via 12 is formed through the use of a drilling method, but any conventional method, such as punching, laser drilling, or photo-definition, can be used. The via 12 can be any diameter, but is preferably in the range between about 2 mils and about 25 mils. Preferably, all or substantially all of the openings or holes in the insulator substrate 10 are formed at the same time, whether they are ultimately to be filled, as described below, or not. This avoids misregistration, especially from tolerance buildups, that can occur between the filled and unfilled vias 12 between the separate hole forming processes and subsequently formed wiring patterns that are formed by the use of one or more masks that must be registered with the vias 12. This factor is especially important as the wiring patterns on the insulator substrate 10 become finer and more dense.

The insulator substrate 10 is provided with a first exterior surface 16 and a second exterior surface 18. As shown in FIG. 1, the via 12 is preferably a through hole extending from the first exterior surface 16 to the second exterior surface 18. However, it should be understood that the via 12 can be a blind via wherein the via 12 does not extend all the way through the insulator substrate 10 from the first exterior surface 16 to the second exterior surface 18.

In the embodiment shown in FIG. 1, the via 12 includes a first conductive plating 22 applied to a sidewall 24 of the via 12. The first conductive plating 22 is applied such that a via hole 26 is defined by the first conductive plating 22. A fill material 28 is positioned within the via hole 26 so as to substantially fill the via hole 26, preferably with as few voids within the fill material 28 as possible. The fill material 28 is preferably applied into the via hole 26 while the fill material 28 is in a flowable state. Suitable examples of the fill material 28 include conductive paste, conductive ink, or non-conductive paste or epoxy. In general, the conductive fill materials are flowable materials including conductive particulates suspended within a binder. The binder hardens or cures within the via hole 26. A conductive pad 30 is applied to each end of the fill material 28, such that the conductive pad extends over at least a portion of the first or second exterior surfaces 16 or 18 of the insulator substrate 10, and also extends over the fill material 28. The conductive pad 30 forms a land or connection point to allow an exterior component, such as an integrated circuit to connect to the conductive pad 30. The conductive pad 30 is any pad that can be configured in any manner so as to be suitable for connecting the component thereto. For example, the conductive pad 30 can be configured as a surfacemount pad, a ball grid array pad, a via-in-pad, or a test-point/test pad.

As will be understood by one skilled in the art, the first conductive plating 22, and/or the fill material 28 cooperate to conduct the electrical signals from the conductive pad 30 to one or more internal signal layers 34 or 36 provided within the insulator substrate 10.

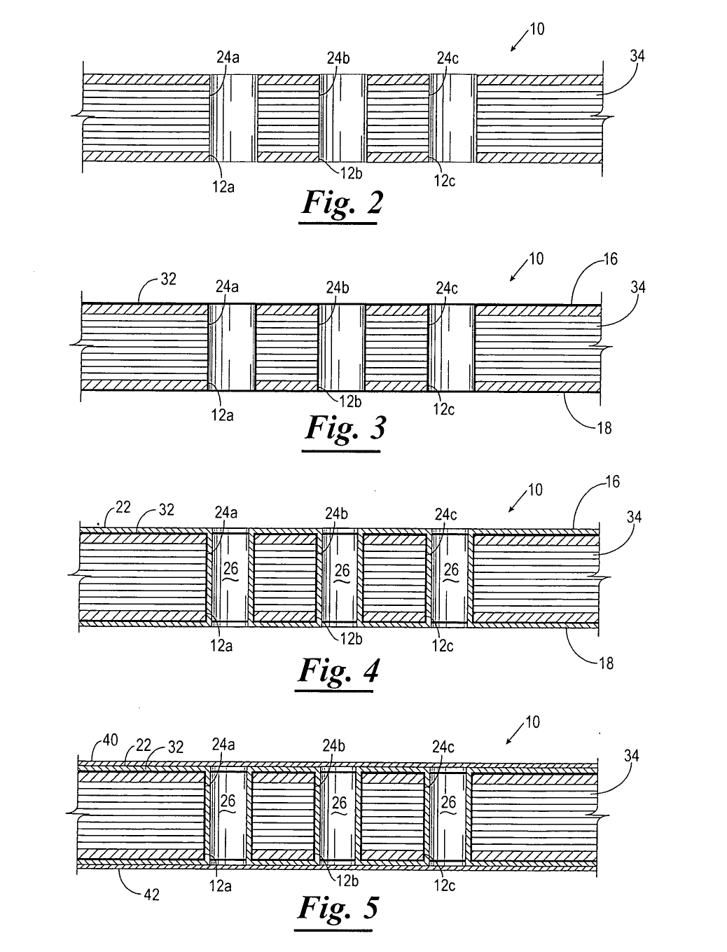

Referring now to FIGS. 2-9, one embodiment of forming the insulator substrate 10 will be described in more detail. It should be understood that the method depicted in FIGS. 2-9 illustrates an embodiment wherein the first conductive plating 22 is applied to the sidewall 24 of the via 12. If a conductive material is used for the fill material 28, such as conductive ink or conductive paste, then the steps described in forming the first conductive plating 22 are optional.

Referring now to FIG. 2, shown therein is the insulator substrate 10 having a plurality of vias 12 formed therein. The vias 12 can be formed by any suitable manner, such as mechanical drilling, punching, laser drilling, milling, or the like. For purposes of clarity, the vias 12 are labeled in FIG. 2 by way of reference numerals 12a, 12b, and 12c. Likewise, the sidewalls 24 are labeled in FIG. 2 with reference numerals 24a, 24b and 24c for purposes of clarity.

FIGS. 3 and 4 illustrate the formation of the first conductive plating 22 on the first exterior surface 16, the second exterior surface 18, and the sidewalls 24 of the vias 12. More specifically, FIG. 3 illustrates a surface preparation step on the exterior surface 16, the second exterior surface 18, and the sidewalls 24 to form a plating 32. Preferably, the surface preparation step uses electroless plating. However, it should be understood that the surface preparation step can use any suitable process capable of preparing the first exterior surface 16, the second exterior surface 18, and the sidewalls 24 for a subsequent plating process to form the first conductive plating 22. As shown in FIG. 4, a conductive material is applied to the plating 32 on first exterior surface 16, the second exterior surface 18, and the sidewalls 24 to form the first conductive plating 22. Preferably, the first conductive plating 22 is provided with a substantially uniform thickness throughout. The thickness of the 1st C.P. can be in a range from about 5 to 40 micrometers. In one preferred embodiment, the first conductive plating 22 is applied by an electrolytic plating process. A suitable electrolytic plating process is described in U.S. Ser. No. 10/273,820, filed on Oct. 18, 2002, the entire content of which is hereby incorporated herein by reference.

The first conductive plating 22 is preferably formed of a conductive metallic material, such as copper, aluminum, gold, or silver. However, it should be understood that the first conductive plating 22 does not necessarily need to be constructed of a metallic material. In this regard, it may be possible to form the first conductive plating 22 by way of a matrix material having conductive filaments or particles embedded therein. A suitable conductive filament may be the carbon structure known in the art as a “nanotube.”

Shown in FIG. 5 is a first removable layer 40 and a second removable layer 42. The first removable layer 40 is applied to the first exterior surface 16. The second removable layer is applied to the second exterior surface 18. The first removable layer and the second removable layer 40 and 42 are constructed of material(s) capable of spanning and thereby sealing off the vias 12 while also adhering to the first and second exterior surfaces 16 and 18. The first removable layer 40 and the second removable layer 42 can adhere to the first exterior surface 16 and the second exterior surface 18, respectively, by using adhesive, temperature, pressure, or the like. In one preferred embodiment, the first and second removable layers 40 and 42 can be characterized as a pressure foil formed of a plastic material such as organic film having a suitable adhesive or cohesive bonding material thereon. The adhesive or cohesive bonding material serves to connect the first and second removable layers 40 and 42 to the first and second exterior surfaces 16 and 18. As discussed above, the first and second removable layers 40 and 42 extend across or span the vias 12 so as to seal off the vias 12 from the exterior environment. A variety of types of lasers can be used, such as a CO₂ laser, YAg laser or an excimer laser.

Referring now to FIG. 6, at least one access hole 46 (and in this example, four access holes 46a, 46b, 46c, and 46d) are formed in the removable layers 40 and 42 such that the access holes 46a, 46b, 46c, and 46d overlap with the vias 12a and 12c to form a mask. Preferably, the access holes 46a and 46c are formed with a laser capable of cutting the removable layers 40 and 42 without damaging the first conductive plating 22. The openings in the foil can also be formed with photo-image, development, laser ablation, or the like. However, it should be understood that other manners of forming the access holes 46a and 46d can be used, such as mechanical drilling, plasma cutting, milling, or the like. It should be noted that the access holes 46a and 46d are formed with respect to predetermined ones of the vias 12 formed in the insulator substrate 10. The predetermined ones of the vias 12 are referred to herein as “target holes.” In this case, the access holes 46a and 46d are positioned adjacent to the target holes 12a and 12c.

Referring to FIG. 7, the target holes 12a and 12c are then filled with the fill material 28 through the access holes 46a and 46b. A suction is applied to the access holes 46c and 46d to draw the fill material 28 into the target holes 12a and 12c. The fill material 28 can be inserted into the target holes 12a and 12c via any suitable method, such as screen printing, pressure head, jetting, or with a syringe or nozzle type device inserted into the target hole. The mask shields the holes 12a and 12c from the via-plugging material applied by either squeegee method, pressure head, roller-coating, ink-jetting, and the like.

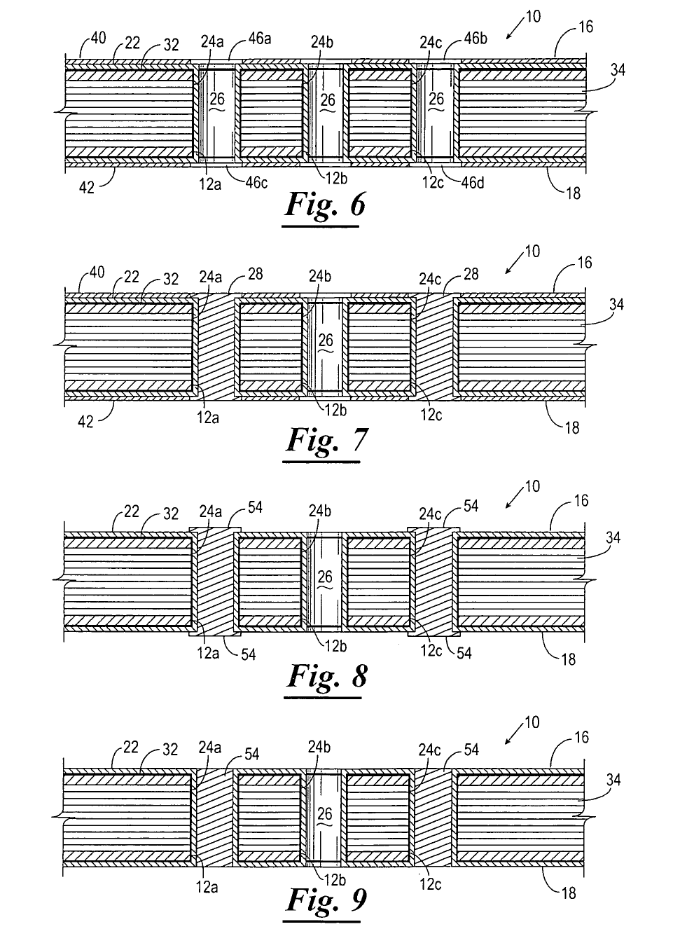

As shown in FIGS. 8 and 9, once the fill material 28 has cured the removable layers 40 and 42 are then removed. The removable layers 40 and 42 can be removed before or after baking the ink or plugging material. Typically, a raised portion 54 of the fill material 28 extends a distance above the exterior surfaces 16 and 18 of the insulator substrate due to the thickness of the removable layers 40 and 42. The size of the raised portions 54 are exaggerated in FIG. 8 for purposes of clarity. In certain instances, the raised portions 54 are suitable for forming a mounting pad for mounting an electrical component thereto. However, as shown in FIG. 9, it is typically desirable to planarize the insulator substrate 10 so as to remove the raised portions 54 extending from the target holes 12a and 12b. The raised portions 54 can be planed by way of a cutting device, or an abrasive sander.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed is:

1. A method for forming a mask for filling at least one target hole defined in a multilayer circuit board, the method comprising the steps of:
applying a removable layer to an exterior surface of the multilayer circuit board; and
forming at least one access hole in the removable layer wherein the at least one access hole in the removable layer overlaps with the at least one target hole to form the mask.

2. The method of claim 1, further comprising:
filling the at least one target hole defined in the multilayer circuit board with a fill material through the access hole; and
removing at least a portion of the removable layer from the multilayer circuit board.

3. The method of claim 1, wherein the exterior surface of the multilayer circuit board is formed of a metallic material and wherein the step of forming the access hole in the removable layer is defined further as forming the access hole with a laser configured to cut through the removable layer without cutting through the metallic material forming the exterior surface of the multilayer circuit board.

4. The method of claim 1 wherein the removable layer is applied with an adhesive or cohesive bonding material to bond the removable layer to the exterior surface of the multilayer circuit board.

5. The method of claim 1 wherein the at least one target hole defined in the multilayer circuit board is a blind via.

6. The method of claim 1 wherein the at least one target hole defined in the multilayer circuit board is a through via.

7. The method of claim 2, wherein the fill material is a conductive material.

8. The method of claim 2, wherein the fill material is a non-conductive material.

9. The method of claim 2 wherein the fill material forms a mounting pad positioned on the exterior surface of the multilayer circuit board and wherein the method further comprises the step of connecting a conductive structure to the mounting pad.

10. The method of claim 2, further comprising the step of:
leveling the fill material to be about level with the exterior surface of the multilayer circuit board.

11. A method for filling at least one target hole defined in a multilayer circuit board, the method comprising the steps of:
plating the at least one target hole with a conductive material;
applying a removable layer to an exterior surface of the multilayer circuit board;
forming at least one access hole in the removable layer wherein the at least one access hole in the removable layer overlaps with the at least one target hole to form a mask;
filling the at least one target hole defined in the multilayer circuit board with a fill material through the access hole; and
removing at least a portion of the removable layer from the multilayer circuit board.

12. The method of claim 11 wherein the step of plating the at least one target hole with a conductive material includes electroless plating of a sidewall of the at least one target hole.

13. The method of claim 11 wherein the removable layer is applied with an adhesive or cohesive bonding material to bond the removable layer to the exterior surface of the multilayer circuit board.

14. The method of claim 11, wherein the exterior surface of the multilayer circuit board is formed of a metallic material and wherein the step of forming the access hole in the removable layer is defined further as forming the access hole with a laser configured to cut through the removable layer without cutting through the metallic material forming the exterior surface of the multilayer circuit board.

15. The method of claim 11 wherein the at least one target hole defined in the multilayer circuit board is a blind via.

16. The method of claim 11 wherein the at least one target hole defined in the multilayer circuit board is a through via.

17. The method of claim 11, wherein the fill material is a non-conductive material.

18. The method of claim 11 wherein the fill material forms a mounting pad positioned on the exterior surface of the multilayer circuit board and wherein the method further comprises the step of connecting a conductive structure to the mounting pad.

19. The method of claim 11, further comprising the step of:
leveling the fill material to be about level with the exterior surface of the multilayer circuit board.

20. A method for filling at least one target hole defined in a multilayer circuit board, the method comprising the steps of:
applying a removable layer to an exterior surface of the multilayer circuit board;
forming at least one access hole in the removable layer wherein the at least one access hole in the removable layer overlaps with the at least one target hole to form a mask;
filling the at least one target hole defined in the multilayer circuit board with a conductive fill material through the access hole; and
removing at least a portion of the removable layer from the multilayer circuit board.

21. The method of claim 20, wherein the step of forming the access hole in the removable layer is defined further as drilling the hole.

22. The method of claim 20 wherein the removable layer is applied with an adhesive or cohesive bonding material to bond the removable layer to the exterior surface of the multilayer circuit board.

23. The method of claim 20, wherein the exterior surface of the multilayer circuit board is formed of a metallic material and wherein the step of forming the access hole in the removable layer is defined further as forming the access hole with a laser configured to cut through the removable layer without cutting through the metallic material forming the exterior surface of the multilayer circuit board.

24. The method of claim 20 wherein the at least one target hole defined in the multilayer circuit board is a blind via.

25. The method of claim 20 wherein the at least one target hole defined in the multilayer circuit board is a through via.

26. The method of claim 20 wherein the fill material forms a mounting pad positioned on the exterior surface of the multilayer circuit board and wherein the method further comprises the step of connecting a conductive structure to the mounting pad.

27. The method of claim 20, further comprising the step of:
leveling the fill material to be about level with the exterior surface of the multilayer circuit board.

28. A mask for filling at least one target hole defined in a multilayer circuit board, the mask formed by a process comprising the steps of:
applying a removable layer to the multilayer circuit board; and
forming at least one access hole in the removable layer wherein the at least one access hole in the removable layer overlaps with the at least one target hole to form the mask.

29. The process of claim 28, further comprising:
filling the at least one target hole defined in the multilayer circuit board with a fill material through the access hole; and
removing at least a portion of the removable layer from the multilayer circuit board.

30. The process of claim 28, wherein the step of forming the access hole in the removable layer is defined further as drilling the hole.

31. The method of claim 28 wherein the removable layer is applied with an adhesive or cohesive bonding material to bond the removable layer to the exterior surface of the multilayer circuit board.

32. The process of claim 28 wherein the at least one target hole defined in the multilayer circuit board is a blind via.

33. The process of claim 28 wherein the at least one target hole defined in the multilayer circuit board is a through via.

34. The process of claim 29, wherein the fill material is a conductive material.

35. The process of claim 29, wherein the fill material is a non-conductive material.

36. The process of claim 29 wherein the fill material forms a mounting pad positioned on the exterior surface of the multilayer circuit board and wherein the method further comprises the step of connecting a conductive structure to the mounting pad.

37. The process of claim 29, further comprising the step of:
leveling the fill material to be about level with the exterior surface of the multilayer circuit board.

38. A multilayer circuit board formed by a process comprising the steps of:
forming at least one target hole in at least a portion of a multilayer;
applying a removable layer to the multilayer;
forming at least one access hole in the removable layer wherein the at least one access hole in the removable layer overlaps with the at least one target hole;
filling the at least one target hole defined in the multilayer with a fill material through the access hole; and
removing at least a portion of the removable layer from the multilayer.

39. The process of claim 38 further comprising the step of plating at least one target hole with a conductive material.

40. The process of claim 39 wherein the step of plating the at least one target hole with a conductive material includes electroless plating of the at least one target hole.

41. The process of claim 38 wherein the step of forming the access hole in the removable layer is defined further as drilling the hole.

42. The method of claim 38, wherein the exterior surface of the multilayer circuit board is formed of a metallic material and wherein the step of forming the access hole in the removable layer is defined further as forming the access hole with a laser configured to cut through the removable layer without cutting through the metallic material forming the exterior surface of the multilayer circuit board.

43. The process of claim 38, wherein the at least one target hole defined in the multilayer is a blind via.

44. The process of claim 38, wherein the at least one target hole defined in the multilayer is a through via.

45. The process of claim 38, wherein the fill material is a non-conductive material.

46. The process of claim 38, wherein the fill material forms a mounting pad positioned on the exterior surface of the multilayer and wherein the process further comprises the step of connecting a conductive structure to the mounting pad.

47. The process of claim 38, further comprising the step of:
leveling the fill material to be about level with the exterior surface of the multilayer.
